(19) United States
(12) Patent Application Publication
(10) Pub. No.: US 2025/0107293 A1
(43) Pub. Date: Mar. 27, 2025

(54) DISPLAY SCREEN ENCAPSULATION STRUCTURE AND PREPARATION METHOD THEREOF AND DISPLAY SCREEN

(71) Applicant: Xiamen Extremely PQ Display Technology Co., Ltd., Xiamen (CN)

(72) Inventor: YONG FAN, Xiamen (CN)

(21) Appl. No.: 18/897,854

(22) Filed: Sep. 26, 2024

Related U.S. Application Data
(63) Continuation of application No. PCT/CN2024/113630, filed on Aug. 21, 2024.

(30) Foreign Application Priority Data
Sep. 26, 2023 (CN) 2023112491732

(51) Int. Cl. H01L 33/54; H01L 25/075; H01L 25/16; H01L 33/00; H01L 33/58

(52) U.S. Cl. CPC H10H 20/853; H01L 25/0753; H01L 25/167; H10H 20/01; H10H 20/855; H10H 20/0362; H10H 20/0363; H10H 20/882

(57) ABSTRACT

A display screen encapsulation structure includes: a drive substrate including a display area and a non-display area surrounding the display area; multiple light-emitting devices spaced apart in the display area; a transparent layer covering the light-emitting devices, and filling a gap area between the multiple light-emitting devices and a peripheral area; a light-shielding layer covering parts of the transparent layer in the gap area and the peripheral area; and an encapsulation layer covering the light-shielding layer and parts of the transparent layer on the light-emitting devices. A side of each light-emitting device facing away from the drive substrate is provided with a light-emitting surface. A surface of the light-shielding layer away from the drive substrate is not higher than the light-emitting surface of each light-emitting device. The display screen encapsulation structure realizes planarization of the drive substrate and improves a light utilization rate of sides of the light-emitting devices.

### CROSS-REFERENCE TO RELATED APPLICATIONS

This application is a continuation of International Patent Application No. PCT/CN2024/113630, filed Aug. 21, 2024, which claims the priority of Chinese Patent Application No. 2023112491732, filed Sep. 26, 2023, both of which are herein incorporated by reference in their entirety.

### TECHNICAL FIELD

The disclosure is related to the field of display technologies, and more particularly to a display screen encapsulation structure, a display screen, and a preparation method of the display screen encapsulation structure.

### BACKGROUND

Micro light-emitting diode (Micro-LED) is a new type of LED with a very small size, typically ranging from a few micrometers (μm) to a few millimeters (mm). Compared to traditional display devices such as liquid crystal display (LCD) and organic light-emitting diode (OLED), micro-LED device has greater performance advantages, such as high brightness, high response speed, low power consumption, and long lifespan. Therefore, the micro-LED holds significant market application prospects in the field of display technologies.

For non-transparent micro-LED displays, achieving better picture quality requires a high environmental contrast ratio and a low reflectivity. However, in the related art, an encapsulation method for a micro-LED display includes: preparing patterned black matrix (BM) on an upper cover plate, defining light-emitting holes on a top surface of a light-emitting device, and then combining a side of the upper cover plate with the patterned BM with the top surface of the light-emitting device. The encapsulation method hardly reduces a formal light-emitting angle; however, the encapsulation method fails to utilize light from sides of the light-emitting device, and a position of the light-emitting device is prone to shift, leading to color shift at wide viewing angles.

In order to enhance the light energy utilization of the light-emitting device and reduce the color shift at the wide viewing angles, the disclosure provides a display screen encapsulation structure, a display screen, and a preparation method of the display screen encapsulation structure.

### SUMMARY

In response to above problems and shortcomings of micro-LED displays in the related art, the disclosure provides a display screen encapsulation structure, a display screen and a preparation method of the display screen encapsulation structure. In the display screen encapsulation structure, a transparent layer covers light-emitting devices and fills a gap area between the light-emitting devices and a peripheral area of the light-emitting devices, realizing planarization of a drive substrate. A light-shielding layer covers parts of the transparent layer in the gap area and the peripheral area, and a surface of the light-shielding layer facing away from the drive substrate is not higher than a thickness of each light-emitting device, thereby improving light energy utilization of the light-emitting devices while avoiding color shift at wide viewing angles caused by a position displacement of the light-emitting devices or inconsistencies in a distance between the light-shielding layer and each light-emitting device.

An embodiment of the disclosure provides a display screen encapsulation structure, and the display screen encapsulation structure includes: a drive substrate, multiple light-emitting devices, a transparent layer, a light-shielding layer and an encapsulation layer.

The drive substrate includes a display area and a non-display area surrounding the display area. The multiple light-emitting devices are spaced apart in the display area of the drive substrate, and a side of each light-emitting device facing away from the drive substrate is provided with a light-emitting surface. The transparent layer covers the multiple light-emitting devices, and fills a gap area between the multiple light-emitting devices and a peripheral area of the multiple light-emitting devices. The light-shielding layer covers parts of the transparent layer in the gap area and the peripheral area, and a surface of the light-shielding layer facing away from the drive substrate is not higher than the light-emitting surface of each light-emitting device. The encapsulation layer covers the light-shielding layer and parts of the transparent layer on the multiple light-emitting devices.

In some embodiments, the display screen encapsulation structure further includes a dam disposed in the non-display area of the drive substrate. The dam surrounds the transparent layer, the light-shielding layer and the encapsulation layer.

In some embodiments, in a light-emitting direction of the multiple light-emitting devices, a sum of a thickness of the light-shielding layer and a thickness of the parts of the transparent layer covered by the light-shielding layer is less than a thickness of the multiple light-emitting devices.

In some embodiments, a thickness of parts of the transparent layer filling the gap area and the peripheral area is in a range of 1 μm to 7 μm, and a thickness of the light-shielding layer is in a range of 1 μm to 7 μm.

In some embodiments, a thickness of the encapsulation layer is in a range of 10 μm to 200 μm.

In some embodiments, a refraction index of the light-emitting surface of each light-emitting device is greater than a refraction index of the transparent layer, and the refraction index of the transparent layer is greater than a refraction index of the encapsulation layer.

In some embodiments, the refraction index of the transparent layer is in a range of 1.47 to 1.7, and the refraction index of the encapsulation layer is in a range of 1.3 to 1.52.

In some embodiments, the refraction index of the light-shielding layer is in a range of 1.3 to 1.52.

In some embodiments, the encapsulation layer includes scattering particles dispersed therein.

In some embodiments, a side of the encapsulation layer facing away from the drive substrate is provided with a lens array, and the lens array includes at least one micro lens.

An embodiment of the disclosure provides a preparation method of a display screen encapsulation structure, including:
providing a drive substrate, where the drive substrate includes a display area and a non-display area surrounding the display area;
providing multiple light-emitting devices, where the multiple light-emitting devices are disposed spaced apart in the display area of the drive substrate, and a side of each light-emitting device facing away from the drive substrate is provided with a light-emitting surface;
forming a transparent layer, where the transparent layer covers the multiple light-emitting devices and fills a peripheral area of the multiple light-emitting devices and a gap area between the multiple light-emitting devices;
forming a light-shielding layer, where the light-shielding layer covers parts of the transparent layer in the gap area and the peripheral area and a surface of the light-shielding layer facing away from the drive substrate is not higher than the light-emitting surface of each light-emitting device; and
forming an encapsulation layer, where the encapsulation layer covers the light-shielding layer and parts of the transparent layer on the multiple light-emitting devices.

In some embodiments, the preparation method of the display screen encapsulation structure further includes: forming a dam. The dam is formed in the non-display area of the drive substrate and the dam surrounds the transparent layer, the light-shielding layer and the encapsulation layer.

An embodiment of the disclosure provides a display screen. The display screen includes a housing, and at least one display unit disposed in the housing. The at least one display unit includes the display screen encapsulation structure provided by the disclosure.

The display screen encapsulation structure, the display screen and the preparation method of the display screen encapsulation structure of the disclosure have the following beneficial effects.

In the display screen encapsulation structure, the transparent layer covers the multiple light-emitting devices and fills the gap area between the multiple light-emitting devices and the peripheral area of the multiple light-emitting devices, realizing the planarization of the drive substrate, and improving a utilization rate of light emitted from sides of the multiple light-emitting devices. The light-shielding layer covers the parts of the transparent layer in the gap area and the peripheral area, realizing patterning of the light-shielding layer, and the surface of the light-shielding layer facing away from the drive substrate is not higher than the light-emitting surface of each light-emitting device, avoiding the color shift at wide viewing angles caused by the position displacement of the light-emitting devices or the inconsistencies in the distance between the light-shielding layer and each light-emitting device.

### BRIEF DESCRIPTION OF DRAWINGS

FIG. 1 illustrates a schematic sectional diagram of a micro-LED display screen encapsulation structure in the related art.

FIG. 2 illustrates a schematic sectional diagram of a first display screen encapsulation structure according to an embodiment 1 of the disclosure.

FIG. 3 illustrates a top view of the first display screen encapsulation structure according to the embodiment 1 of the disclosure.

FIG. 4 illustrates a schematic sectional diagram of a second display screen encapsulation structure according to the embodiment 1 of the disclosure.

FIG. 5 illustrates a schematic sectional diagram of a third display screen encapsulation structure according to the embodiment 1 of the disclosure.

FIG. 6 illustrates a schematic sectional diagram of a display screen encapsulation structure according to an embodiment 2 of the disclosure.

FIG. 7 illustrates a schematic sectional diagram of a display screen encapsulation structure according to an embodiment 3 of the disclosure.

FIG. 8 illustrates a schematic sectional diagram of another display screen encapsulation structure according to the embodiment 3 of the disclosure.

FIG. 9 illustrates a flow chart of a preparation method of a display screen encapsulation structure according to an embodiment 4 of the disclosure.

FIG. 10 to FIG. 12 illustrate schematic intermediate structural diagrams of a forming process of the display screen encapsulation structure according to the embodiment 4 of the disclosure.

FIG. 13 illustrates a top view of a display screen according to an embodiment 5 of the disclosure.

### DESCRIPTION OF REFERENCE NUMERALS

11: drive substrate; 12: LED chip; 13: encapsulation layer; 14: upper substrate; 15: light-transmitting layer; 16: light-shielding layer; 100: drive substrate; 101: non-display area; 102: display area; 110: light-emitting device; 120: transparent layer; 130: light-shielding layer; 140: encapsulation layer; 150: dam; 160: lens array; 201: housing; 202: display unit; 1101: light-emitting surface; 1021: gap area; 1022: peripheral area.

### DETAILED DESCRIPTION OF EMBODIMENTS

The implementation of the disclosure is described below through specific embodiments, and those skilled in the art can easily understand other advantages and effects of the disclosure from the contents disclosed in this specification. The disclosure can also be implemented or applied by other different specific embodiments, and various details in this specification can be modified or changed based on different viewpoints and applications without departing from the spirit of the disclosure.

Referring to FIG. 1, in the related art, a micro-LED display includes a drive substrate 11 and an upper substrate 14 which are disposed facing towards each other. A side of the drive substrate 11 close to the upper substrate 14 is provided with multiple LED chips 12 at intervals. A side of each LED chip 12 facing away from the drive substrate 11 is provided with a light-emitting surface. An encapsulation layer 13 wraps around the multiple LED chips 12 and covers a gap area and a peripheral area of the multiple LED chips 12. A side of the upper substrate 14 close to the drive substrate 11 is provided with multiple light-transmitting layers 15 at intervals. A gap area and a peripheral area of the multiple light-transmitting layers 15 are filled with a light-shielding layer 16. A patterned BM is formed on the upper substrate 14. The drive substrate 11 is combined with the upper substrate 14. The multiple light-transmitting layers 15 correspond to the light-emitting surfaces of the multiple LED chips 12 one to one. The light-shielding layer 16 corresponds to the encapsulation layer 13 covering the gap area and the peripheral area of the multiple LED chips 12. The micro-LED display hardly reduces a formal light-emitting angle. However, light from sides of the LED chips 12 cannot be emitted due to the reflection and absorption by the light-shielding layer 16, resulting in a low light utilization rate. Moreover, positions of the LED chips 12 are prone to deviation relative to a position of the light-shielding layer 16, leading to color shift at wide viewing angles. Meanwhile, an encapsulation of the micro-LED display in the related art requires precise positioning with hard attachment, which leads to high process costs.

In response to above shortcomings, the disclosure provides a display screen encapsulation structure, which is described below in detail.

### Embodiment 1

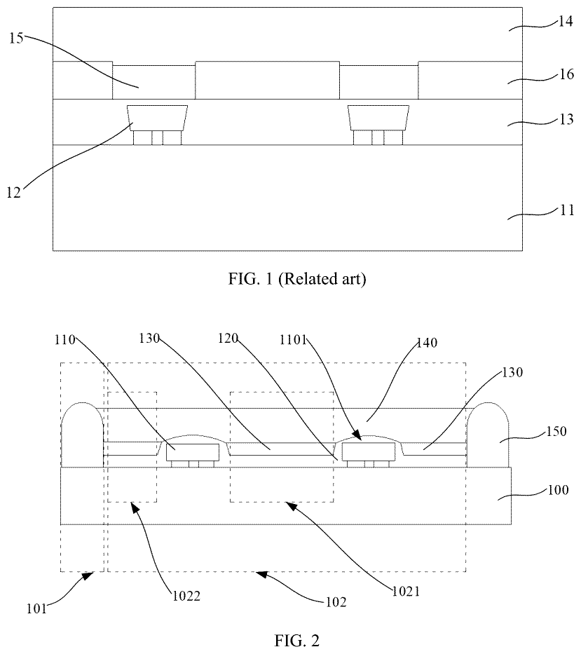

The embodiment provides a display screen encapsulation structure. As shown in FIG. 2, the display screen encapsulation structure of the embodiment includes a drive substrate 100, multiple light-emitting devices 110, a transparent layer 120, a light-shielding layer 130, an encapsulation layer 140 and a dam 150. The drive substrate 100 includes a display area 102 and a non-display area 101 surrounding the display area 102. The multiple light-emitting devices 110 are spaced apart in the display area 102, and a side of each light-emitting device 110 facing away from the drive substrate 100 is provided with a light-emitting surface 1101. The drive substrate 100 is configured to drive the multiple light-emitting devices 110 to emit light. The multiple light-emitting devices 110 are LED chips. Optionally, the LED chips are micro-LED chips. The LED chips can be vertically structured LED chips or flip-chip structured LED chips.

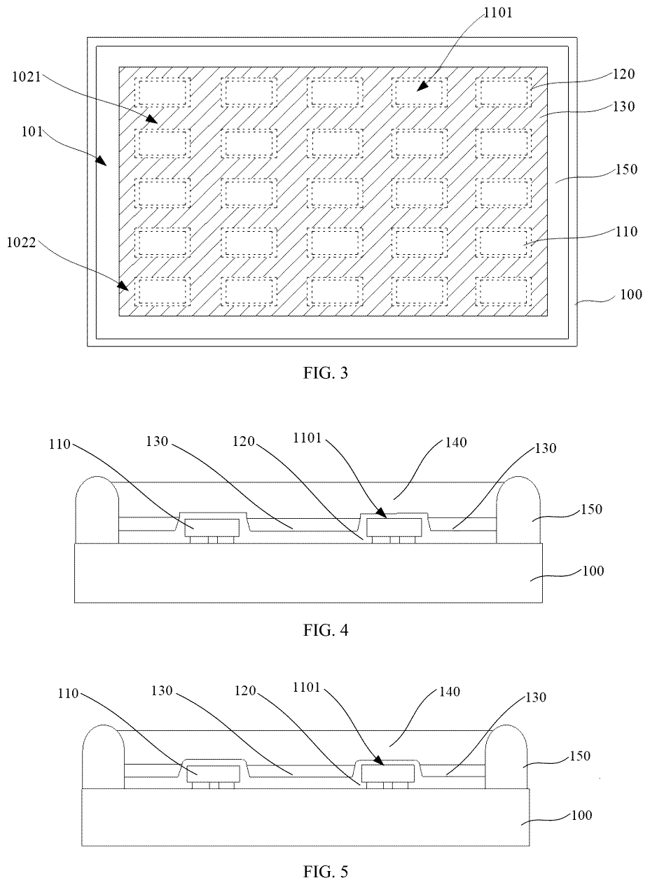

As shown in FIG. 2 and FIG. 3, the transparent layer 120 wraps around the multiple light-emitting devices 110 and fills a gap area 1201 between the multiple light-emitting devices 110 and a peripheral area 1022 of the multiple light-emitting devices 110. As shown in FIG. 2, FIG. 4 and FIG. 5, parts of the transparent layer 120 covering the light-emitting surfaces 1101 of the multiple light-emitting devices 110 can form different shapes according to actual needs, e.g., an arc shape (as shown in FIG. 2) or a rectangle. When forming the rectangle, two corners of the rectangle facing away from the light-emitting surface 1101 of the light-emitting device 110 can be right-angled (as shown in FIG. 4) or rounded (as shown in FIG. 5). The transparent layer 120 fills the peripheral area 1022 and the gap area 1021 between the light-emitting devices 110, which is conducive to realizing planarization of the drive substrate 100.

As shown in FIG. 2 and FIG. 3, the light-shielding layer 130 covers parts of the transparent layer 120 in the gap area 1021 and the peripheral area 1022, realizing the patterning of the light-shielding layer 130. A surface of the light-shielding layer 130 facing away from the drive substrate 100 is not higher than the light-emitting surface 1101 of each light-emitting device 110, avoiding a position displacement of the light-emitting devices 110 or inconsistencies in a distance between the light-shielding layer 130 and each light-emitting device 110, thereby avoiding color shift at wide viewing angles. The light-shielding layer 130 can be a light-absorbing material layer, such as a black adhesive layer. Since the transparent layer 120 wraps around the light-emitting devices 110, i.e., the transparent layer 120 with a certain thickness is provided around the light-emitting devices 110, the light-shielding layer 130 has certain gaps with the light-emitting devices 110 in a horizontal direction. Due to the gaps between the light-shielding layer 130 and the light-emitting devices 110, the light-shielding layer 130 can reflect some of light emitted from sides of the light-emitting devices 110 into the transparent layer 120, reflected light then emits from the transparent layer 120 (parts on the light-emitting surfaces 1101 of the light-emitting devices 110), while some light is emitted directly from the certain gaps between the light-shielding layer 130 and the light-emitting devices 110, improving a utilization rate of the light emitted from the sides of the light-emitting devices 110. The light-shielding layer 130 is also configured to avoid light crosstalk between adjacent light-emitting devices 110. A gap width between the light-shielding layer 130 and each light-emitting device 110 in a horizontal direction is in a range of 0.1 μm to 3 μm. Specifically, the gap width can be, for example, 0.1 μm, 0.5 μm, 1 μm, 1.5 μm, 2 μm, 2.5 μm and 3 μm.

As shown in FIG. 2, the encapsulation layer 140 covers the light-shielding layer 130 and the parts of the transparent layer 120 on the multiple light-emitting devices 110. The encapsulation layer 140 encapsulates the light-shielding layer 130 and the transparent layer 120, achieving sealing of a display screen, which can prevent water, dust and corrosion, etc., and extend the service life of the display screen. The dam 150 is disposed in the non-display area 101 of the drive substrate 100. The dam 150 surrounds the transparent layer 120, the light-shielding layer 130 and the encapsulation layer 140. The dam 150 can prevent the overflow of fluids during a formation of the transparent layer 120 and the light-shielding layer 130, which is conducive to the planarization of the drive substrate 100 and the patterning of the light-shielding layer 130. Meanwhile, the dam 150 can also reflect the light emitted from the sides of the light-emitting devices 110, enhancing the brightness of the light-emitting devices 110. It is understandable that a thickness of the dam 150 is greater than a sum of a thickness of the light-emitting devices 110 and a thickness of the parts of the transparent layer 120 on the light-emitting surfaces 1101. The material of the dam 150 can be silicone, etc. The encapsulation layer 140 encapsulates the display area 102 surrounded by the dam 150 and sides of the dam 150 close to the display area 102.

In an alternative embodiment, the transparent layer 120 and the light-shielding layer 130 can be formed through rapid inkjet printing, without the need for precise vacuum alignment equipment with hard bonding, which reduces the process cost and improves the process efficiency.

In an alternative embodiment, as shown in FIG. 2, in a light-emitting direction of the light-emitting devices 110, a sum of a thickness of the light-shielding layer 130 and the thickness of the parts of the transparent layer 120 covered by the light-shielding layer 130 is less than the thickness of the light-emitting device 110, which is beneficial to prevent the position displacement of the light-emitting device 110 or the inconsistencies in the distance between the light-shielding layer 130 and each light-emitting device 110, thereby avoiding the color shift at wide viewing angles and is also conducive to the planarization of the drive substrate 100. Optionally, a thickness of parts of the transparent layer 120 filling the gap area 1021 and the peripheral area 1022 is in a range of 1 μm to 7 μm. Specifically, the thickness of the parts of the transparent layer 120 filling the gap area 1021 and the peripheral area 1022 can be, for example, 1 μm, 2 μm, 3 μm, 4 μm, 5 μm, 6 μm and 7 μm etc. Optionally, the thickness of the light-shielding layer 130 is in a range of 1 μm to 7 μm. Specifically, the thickness of the light-shielding layer 130 can be, for example, 1 μm, 2 μm, 3 μm, 4 μm, 5 μm, 6 μm and 7 μm etc. Optionally, the thickness of each light-emitting device 110 is in a range of 6 μm to 14 μm. Specifically, the thickness of each light-emitting device 110 can be, for example, 6 μm, 7 μm, 8 μm, 9 μm, 10 μm, 11 μm, 12 μm, 13 μm and 14 μm etc. Optionally, a thickness of the encapsulation layer 140 is in a range of 10 μm to 200 μm. Specifically, the thickness of the encapsulation layer 140 can be, for example, 10 μm, 30 μm, 50 μm, 70 μm, 90 μm, 110 μm, 130 μm, 150 μm, 170 μm and 200 μm etc.

In an alternative embodiment, a refraction index of the light-emitting surface 1101 of each light-emitting device 110 is greater than a refraction index of the transparent layer 120, and the refraction index of the transparent layer 120 is greater than a refraction index of the encapsulation layer 140, which is conducive to improving light-emitting efficiency of the light-emitting devices 110. Optionally, the refraction index of the transparent layer 120 is in a range of 1.47 to 1.7. Specifically, the refraction index of the transparent layer 120 can be, for example, 1.47, 1.5, 1.6 and 1.7 etc. Optionally, the refraction index of the encapsulation layer 140 is in a range of 1.3 to 1.52. Specifically, the refraction index of the encapsulation layer 140 can be, for example, 1.3, 1.4, 1.5 and 1.52 etc. Optionally, the material of the transparent layer 120 can be transparent organic silicone and epoxy resin, etc. The material of the encapsulation layer 140 can be silicone, or it can be epoxy resin doped with antioxidants, the antioxidants can be one or more selected from the group consisting of antioxidant 168, antioxidant 245, antioxidant 816, antioxidant 1010, antioxidant 1076, antioxidant 1135, and antioxidant 1130 to achieve the antioxidant effect. Optionally, the refraction index of the light-shielding layer 130 is in a range of 1.3 to 1.52. Specifically, the refraction index of the light-shielding layer 130 can be, for example, 1.3, 1.4, 1.5 and 1.52 etc. Since the refraction index of the light-emitting surface 1101 of each light-emitting device 110 is greater than the refraction index of the transparent layer 120, and the refraction index of the transparent layer 120 is greater than the refraction index of the light-shielding layer 130, some of the light emitted from the sides of the light-emitting devices 110 can be reflected by the light-shielding layer 130 and emitted from the light-emitting surfaces 1101 of the light-emitting devices 110.

In an alternative embodiment, the encapsulation layer 140 includes scattering particles dispersed therein, which can correct the light pattern and enhance the brightness at the normal viewing angle. Different types of the scattering particles can scatter light of different target wavelengths, and different sizes of the scattering particles also affect the scattering effect, so the scattering particles can be selected according to actual needs. Optionally, a proportion of the scattering particles in the encapsulation layer 140 ranges from 1% to 20%. Specifically, the proportion of the scattering particles in the encapsulation layer 140 can be 1%, 5%, 10%, 15%, and 20%, etc.

### Embodiment 2

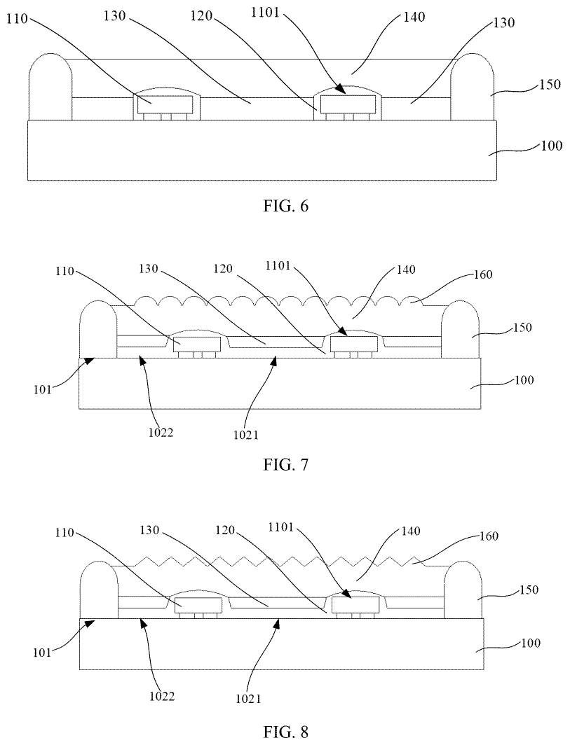

The embodiment 2 provides a display screen encapsulation structure. As shown in FIG. 6, the display screen encapsulation structure of the embodiment includes a drive substrate 100, multiple light-emitting devices 110, a transparent layer 120, a light-shielding layer 130, an encapsulation layer 140 and a dam 150. Similarities with the display screen encapsulation structure of the embodiment 1 are not reiterated here, and differences are as follows.

As shown in FIG. 6, the transparent layer 120 only wraps around the light-emitting devices 110. The light-shielding layer 130 fills a gap area 1021 between the multiple light-emitting devices 110 and a peripheral area 1022 of the multiple light-emitting devices 110. A surface of the light-shielding layer 130 facing away from the drive substrate 100 is not higher than a light-emitting surface 1101 of each light-emitting device 110, avoiding color shift at wide viewing angles caused by a position displacement of the light-emitting devices 110 or inconsistencies in a distance between the light-shielding layer 130 and each light-emitting device 110.

Since the transparent layer 120 wraps around the light-emitting devices 110, the light-shielding layer 130 has a certain gap with each light-emitting device 110. Specifically, in a horizontal direction, a width of the gap is determined by a width of the transparent layer 120 that encapsulates the light-emitting devices 110 (the width of the transparent layer 120 refers to a width of a part of the transparent layer 120, horizontally, between the light-shielding layer 130 and a side of the light-emitting device 110). Since there is the certain gap between each light-emitting device 110 and the light-shielding layer 130, light from sides of the light-emitting devices 110, after being reflected by the light-shielding layer 130, can exit through the transparent layer 120 in the gap, thereby improving a light utilization rate of the sides of the light-emitting devices 110.

### Embodiment 3

The embodiment 3 provides a display screen encapsulation structure. As shown in FIG. 7 and FIG. 8, the display screen encapsulation structure of the embodiment includes a drive substrate 100, multiple light-emitting devices 110, a transparent layer 120, a light-shielding layer 130, an encapsulation layer 140 and a dam 150. Similarities with the display screen encapsulation structure of the embodiment 1 are not reiterated here, and differences are as follows.

A side of the encapsulation layer 140 facing away from the drive substrate 100 is provided with a lens array 160, and the lens array 160 includes at least one micro lens. The lens array has a focusing effect, which can collect light over a wide viewing angle.

As shown in FIG. 7, the micro lens of the lens array 160 can be similar to a hemispherical structure. As shown in FIG. 8, the micro lens of the lens array 160 can be a pyramidal structure, or structured like a bun, etc. A size of each micro lens can be in a range of 1 μm to 10 μm.

### Embodiment 4

The embodiment 4 provides a preparation method of a display screen encapsulation structure. As shown in FIG. 9, the preparation method includes the following steps 001-005.

Step 001, a drive substrate 100 is provided, and the drive substrate 100 includes a display area 102 and a non-display area 101 surrounding the display area 102.

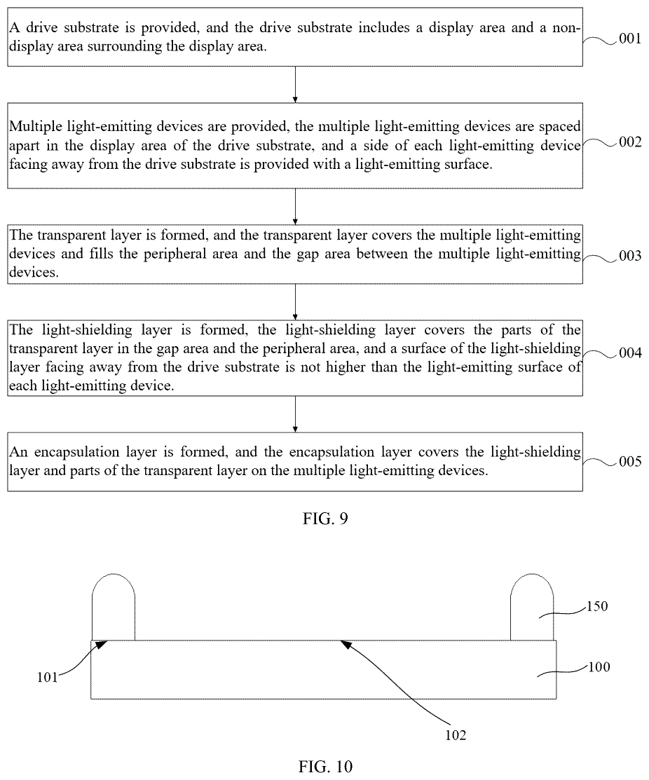

In an alternative embodiment, as shown in FIG. 10, in order to prevent materials used to form a transparent layer 120 and a light-shielding layer 130 from flowing into the non-display area 101 and a peripheral area of the non-display area 101, a dam 150 surrounding the drive substrate 100 is disposed at an edge of the drive substrate 100 before forming the transparent layer 120 and the light-shielding layer 130. An area of the drive substrate 100 where the dam 150 is located is defined as the non-display area 101, and an area of the drive substrate 100 that is surrounded by the dam 150 is defined as the display area 102.

Step 002, multiple light-emitting devices 110 are provided, the multiple light-emitting devices 110 are spaced apart in the display area 102 of the drive substrate 110, and a side of each light-emitting device 110 facing away from the drive substrate 100 is provided with a light-emitting surface 1101.

Specifically, the multiple light-emitting devices 110 are arranged at intervals in the display area 102 of the drive substrate 110, an area between the multiple light-emitting devices 110 is defined as a gap area 1021, an area between the dam 15 and light-emitting devices 110 which are located on a periphery of the drive substrate 100 is defined as a peripheral area 1022, and the side of each light-emitting device 110 facing away from the drive substrate 100 is defined as the light-emitting surface 1101.

Step 003, the transparent layer 120 is formed, and the transparent layer 120 covers the multiple light-emitting devices 110 and fills the peripheral area 1022 and the gap area 1021 between the multiple light-emitting devices 110.

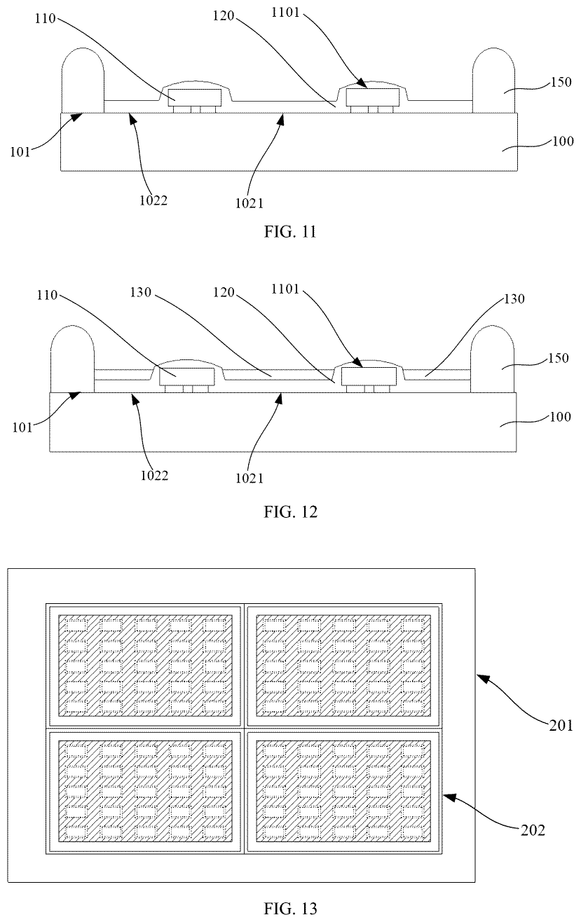

Specifically, as shown in FIG. 11, the light-emitting surfaces 1101 and sides of the multiple light-emitting devices 110 are covered with the transparent layer 120, making the transparent layer 120 cover the multiple light-emitting devices 110 completely. The peripheral area 1022 and the gap area 1021 are filled with the transparent layer 120, a thickness of parts of the transparent layer 120 filling the peripheral area 1022 and the gap area 1021 is less than a thickness of each light-emitting device 110. The transparent layer 120 can realize planarization of the drive substrate 100. The transparent layer 120 can be formed through rapid inkjet printing. Optionally, the thickness of each light-emitting device 110 is in a range of 6 μm to 14 μm. Specifically, the thickness of each light-emitting device 110 can be, for example, 6 μm, 7 μm, 8 μm, 9 μm, 10 μm, 11 μm, 12 μm, 13 μm and 14 μm etc. The thickness of the parts of the transparent layer 120 filling the gap area 1021 and the peripheral area 1022 is in a range of 1 μm to 7 μm. Specifically, the thickness of the part of the transparent layer 120 filling the gap area 1021 and the peripheral area 1022 can be, for example, 1 μm, 2 μm, 3 μm, 4 μm, 5 μm, 6 μm and 7 μm etc.

Step 004, the light-shielding layer 130 is formed, the light-shielding layer 130 covers the parts of the transparent layer 120 in the gap area 1021 and the peripheral area 1022, and a surface of the light-shielding layer 130 facing away from the drive substrate 100 is not higher than the light-emitting surface 1101 of each light-emitting device 110.

Specifically, as shown in FIG. 12, the light-shielding layer 130 is formed on the parts of the transparent layer 120 in the gap area 1021 and the peripheral area 1022. A sum of a thickness of the light-shielding layer 130 and the thickness of the parts of the transparent layer 120 under the light-shielding layer 130 is less than or equal to the thickness of each light-emitting device 110. Preferably, the sum of the thickness of the light-shielding layer 130 and the thickness of the parts of the transparent layer 120 under the light-shielding layer 130 is less than the thickness of each light-emitting device 110, thereby avoiding color shift at wide viewing angles caused by a position displacement of the light-emitting devices 110 or inconsistencies in a distance between the light-shielding layer 130 and each light-emitting device 110. Since the transparent layer 120 wrapping around the sides of the multiple light-emitting devices 110 has a certain thickness, the light-shielding layer 130 has a certain gap with each light-emitting device 110 in a horizontal direction, a size of the gap can be adjusted according to actual needs. Since there is the certain gap between each light-emitting device 110 and the light-shielding layer 130, some of light emitted from the sides of the light-emitting devices 110 is reflected by the light-shielding layer 130 and then emit from the light-emitting surfaces 1101 of the light-emitting devices 110, and some of the light emitted from the sides of the light-emitting devices 110 is reflected by the light-shielding layer 130 and then exit through the transparent layer 120 in the gap, thereby improving a light utilization rate of the sides of the light-emitting devices 110. Optionally, the light-shielding layer 130 is a black light-shielding layer. The light-shielding layer 130 can be formed through rapid inkjet printing, without the need for precise vacuum alignment equipment with hard bonding, which reduces the process cost and improves the process efficiency. Optionally, the thickness of the light-shielding layer 130 is in a range of 1 μm to 7 μm. Specifically, the thickness of the light-shielding layer 130 can be, for example, 1 μm, 2 μm, 3 μm, 4 μm, 5 μm, 6 μm and 7 μm etc. In an alternative embodiment, in order to improve light-emitting effects of the light-emitting devices 110, a refraction index of the light-emitting surface 1101 of each light-emitting device 110 is greater than a refraction index of the transparent layer 120, and the refraction index of the transparent layer 120 is greater than a refraction index of the light-shielding layer 130. Optionally, the refraction index of the transparent layer 120 is in a range of 1.47 to 1.7. Specifically, the refraction index of the transparent layer 120 can be, for example, 1.47, 1.5, 1.6 and 1.7 etc. Optionally, the refraction index of the light-shielding layer 130 is in a range of 1.3 to 1.52. Specifically, the refraction index of the light-shielding layer 130 can be, for example, 1.3, 1.4, 1.5 and 1.52 etc.

Step 005, an encapsulation layer 140 is formed, and the encapsulation layer 140 covers the light-shielding layer 130 and parts of the transparent layer 120 on the multiple light-emitting devices 110.

In an alternative embodiment, as shown in FIG. 2, FIG. 4 and FIG. 5, the encapsulation layer 140 is formed on the light-shielding layer 130 and the parts of the transparent layer 120 on the light-emitting surfaces 1101 of the multiple light-emitting devices 110, and surrounded by the dam 15. Optionally, the encapsulation layer 140 includes scattering particles dispersed therein, which can correct the light pattern. Optionally, a thickness of the encapsulation layer 140 is in a range of 10 μm to 200 μm. Specifically, the thickness of the encapsulation layer 140 can be, for example, 10 μm, 30 μm, 50 μm, 70 μm, 90 μm, 110 μm, 130 μm, 150 μm, 170 μm and 200 μm etc. Optionally, the refraction index of the encapsulation layer 140 is in a range of 1.3 to 1.52. Specifically, the refraction index of the encapsulation layer 140 can be, for example, 1.3, 1.4, 1.5 and 1.52 etc.

In an alternative embodiment, as shown in FIG. 7 and FIG. 8, a side of the encapsulation layer 140 facing away from the drive substrate 100 is provided with a lens array 160, and the lens array 160 includes at least one micro lens. The lens array has a focusing effect, which can collect light over a wide viewing angle. Optionally, as shown in FIG. 7, the micro lens of the lens array 160 can be similar to a hemispherical structure; as shown in FIG. 8, the micro lens of the lens array 160 can be a pyramidal structure, or structured like a bun, etc. A size of each micro lens can be in a range of 1 μm to 10 μm.

### Embodiment 5

The embodiment 5 provides a display screen. As shown in FIG. 13, the display screen includes a housing 201, and at least one display unit 202 disposed in the housing 201. The at least one display unit 202 includes the display screen encapsulation structure provided by any one of the embodiment 1 to the embodiment 3. When the at least one display unit 202 is multiple display units 202, the multiple display units 202 can be connected with each other in series or parallel.

Since the display screen of the embodiment 5 includes the display screen encapsulation structure provided by the embodiment 1 to the embodiment 3, beneficial effects achieved by the display screen encapsulation structure provided by the embodiment 1 to the embodiment 3 can be achieved in the embodiment 5, referring to the embodiments 1-3 for details, which are not repeated here.

The above embodiments are only illustrative of the principles and effects of the disclosure, and are not intended to limit the disclosure. Those skilled in the art may modify or change the above embodiments without departing from the spirit and scope of the disclosure. Therefore, all equivalent modifications or changes made by those skilled in the art without departing from the spirit and technical ideas disclosed in the disclosure should still be covered by the claims of the disclosure.

What is claimed is:

1. A display screen encapsulation structure, comprising:
a drive substrate, comprising a display area and a non-display area surrounding the display area;
a plurality of light-emitting devices, spaced apart in the display area of the drive substrate, wherein a side of each of the plurality of light-emitting devices facing away from the drive substrate is provided with a light-emitting surface;
a transparent layer, covering the plurality of light-emitting devices and filling a gap area between the plurality of light-emitting devices and a peripheral area of the plurality of light-emitting devices;
a light-shielding layer, covering parts of the transparent layer in the gap area and the peripheral area, wherein a surface of the light-shielding layer facing away from the drive substrate is not higher than the light-emitting surface of each of the plurality of light-emitting devices; and
an encapsulation layer, covering the light-shielding layer and parts of the transparent layer on the plurality of light-emitting devices.

2. The display screen encapsulation structure as claimed in claim 1, further comprising: a dam, disposed in the non-display area of the drive substrate, wherein the dam surrounds the transparent layer, the light-shielding layer and the encapsulation layer.

3. The display screen encapsulation structure as claimed in claim 1, wherein in a light-emitting direction of the plurality of light-emitting devices, a sum of a thickness of the light-shielding layer and a thickness of the parts of the transparent layer covered by the light-shielding layer is less than a thickness of the plurality of light-emitting devices.

4. The display screen encapsulation structure as claimed in claim 2, wherein in a light-emitting direction of the plurality of light-emitting devices, a sum of a thickness of the light-shielding layer and a thickness of the parts of the transparent layer covered by the light-shielding layer is less than a thickness of the plurality of light-emitting devices.

5. The display screen encapsulation structure as claimed in claim 1, wherein a thickness of parts of the transparent layer filling the gap area and the peripheral area is in a range of 1 micrometer (μm) to 7 μm, and a thickness of the light-shielding layer is in a range of 1 μm to 7 μm.

6. The display screen encapsulation structure as claimed in claim 2, wherein a thickness of parts of the transparent layer filling the gap area and the peripheral area is in a range of 1 μm to 7 μm, and a thickness of the light-shielding layer is in a range of 1 μm to 7 μm.

7. The display screen encapsulation structure as claimed in claim 1, wherein a thickness of the encapsulation layer is in a range of 10 μm to 200 μm.

8. The display screen encapsulation structure as claimed in claim 2, wherein a thickness of the encapsulation layer is in a range of 10 μm to 200 μm.

9. The display screen encapsulation structure as claimed in claim 1, wherein a refraction index of the light-emitting surface of each of the plurality of light-emitting devices is greater than a refraction index of the transparent layer, and the refraction index of the transparent layer is greater than a refraction index of the encapsulation layer.

10. The display screen encapsulation structure as claimed in claim 1, wherein a refraction index of the transparent layer is in a range of 1.47 to 1.7, and a refraction index of the encapsulation layer is in a range of 1.3 to 1.52.

11. The display screen encapsulation structure as claimed in claim 9, wherein the refraction index of the transparent layer is in a range of 1.47 to 1.7, and the refraction index of the encapsulation layer is in a range of 1.3 to 1.52.

12. The display screen encapsulation structure as claimed in claim 1, wherein a side of the encapsulation layer facing away from the drive substrate is provided with a lens array, and the lens array comprises at least one micro lens.

13. The display screen encapsulation structure as claimed in claim 1, wherein a refraction index of the light-shielding layer is in a range of 1.3 to 1.52.

14. The display screen encapsulation structure as claimed in claim 1, wherein the encapsulation layer comprises scattering particles dispersed therein.

15. The display screen encapsulation structure as claimed in claim 1, wherein a distance between the light-shielding layer and each of the plurality of light-emitting device in a horizontal direction is in a range of 0.1 μm to 3 μm.

16. The display screen encapsulation structure as claimed in claim 1, wherein a thickness of each of the plurality of light-emitting devices is in a range of 6 μm to 14 μm.

17. A preparation method of a display screen encapsulation structure, comprising:
providing a drive substrate, wherein the drive substrate comprises a display area and a non-display area surrounding the display area;
providing a plurality of light-emitting devices, wherein the plurality of light-emitting devices are spaced apart in the display area of the drive substrate, and a side of each of the plurality of light-emitting devices facing away from the drive substrate is provided with a light-emitting surface;
forming a transparent layer, wherein the transparent layer covers the plurality of light-emitting devices and fills a gap area between the plurality of light-emitting devices and a peripheral area of the plurality of light-emitting devices;
forming a light-shielding layer, wherein the light-shielding layer covers parts of the transparent layer in the gap area and the peripheral area, and a surface of the light-shielding layer facing away from the drive substrate is not higher than the light-emitting surface of each of the plurality of light-emitting devices; and
forming an encapsulation layer, wherein the encapsulation layer covers the light-shielding layer and parts of the transparent layer on the plurality of light-emitting devices.

18. The preparation method of the display screen encapsulation structure as claimed in claim 17, further comprising: forming a dam, wherein the dam is formed in the non-display area of the drive substrate and surrounds the transparent layer, the light-shielding layer and the encapsulation layer.

19. A display screen, comprising:
a housing; and
at least one display unit, disposed in the housing;
wherein the at least one display unit comprises the display screen encapsulation structure as claimed in claim 1.

20. The display screen as claimed in claim 19, wherein the display screen encapsulation structure further comprises: a dam, disposed in the non-display area of the drive substrate, and the dam surrounds the transparent layer, the light-shielding layer and the encapsulation layer.
